(19) United States
(12) Patent Application Publication
(10) Pub. No.: US 2025/0304856 A1
(43) Pub. Date: Oct. 2, 2025

(54) Formulated Alkaline Chemistry For Polysilicon Exhume

(71) Applicant: Versum Materials US, LLC, Tempe, AZ (US)

(72) Inventors: Jhih-Kuei Ge, New Taipei City (TW); Yi-Chia Lee, Chupei City (TW); Aiping Wu, Chandler, AZ (US)

(21) Appl. No.: 18/864,038

(22) PCT Filed: Mar. 30, 2023
(86) PCT No.: PCT/US2023/065163

§ 371 Date: Nov. 8, 2024

(51) Int. Cl. C09K 13/00; H01L 21/02; H01L 21/3213

(52) U.S. Cl. CPC C09K 13/00; H01L 21/02068; H01L 21/32134

(57) ABSTRACT

The disclosed and claimed subject matter relates to etching compositions capable of selectively removing a silicon film while minimizing the etch rate of an oxide film as well as method employing the same for fabricating a semiconductor device.

### BACKGROUND

### Field

The disclosed and claimed subject matter relates to etching compositions, and more particularly, to a high-selectivity etching compositions capable of selectively removing a silicon film while minimizing the etch rate of an oxide film and to a method for fabricating a semiconductor, which includes an etching process employing the etching composition.

### Related Art

As semiconductor devices become more highly integrated, the reliability and electrical characteristics of the semiconductor devices are more susceptible to damage or deformation of the layers constituting the semiconductor device. Therefore, when an etching process is performed to remove a specific material layer selectively using an etchant, it is desirable that the etchant should have a higher etch selectivity with respect to other material layers and the etching process generate less byproduct to reduce process defects.

In 3D NAND flash memory device fabrication, as the number of nitride/oxide alternative layers increase, high aspect ratio (HAR) channel etch challenges the physical limits of current plasma etch technologies. To overcome these challenges, process flow has shifted from single stacking to multiple stacking (e.g., 2 decks of 64-layers to provide an equivalent 128-layer array). FIG. 1 illustrates double stacking process. After HAR channel etch of deck 1, the vertical channel will be filled with sacrificial materials. The deck 2 process proceeds on top of deck 1, i.e., nitride/oxide deposition and channel etch. Eventually, the filling material is removed, so that the HAR channel etch for 2× layers can be achieved. The disclosed and claimed subject matter can be used in these processes as a wet etchant for polysilicon removal.

Wet etchant compositions for eliminating pyramid-shaped Si etching residues generated after etching process with high silicon to silicon oxide selectivity are known. For example, U.S. Patent Application Publication No. 2017/0145311 describes etching compositions that can selectively etch certain crystal planes or perform crystal orientation selective wet etching and provide a flat bottom. U.S. Patent Application Publication No. 2020/0157422 describes various kinds of oxide inhibitor that can significantly suppress oxide etch rate in an alkaline wet chemical etching formulation and demonstrates high silicon to silicon oxide selectivity.

Notwithstanding these know materials, and with such high integration, the material selectivity requirement for selective silicon sacrificial removal in 3D NAND fabrication becomes more critical—to the point where it is desired to effectively leave the SiOₓ layer unchanged while etching the silicon layer. Thus, there is a need in the art to further suppress the SiOₓ etch rate to achieve an even higher silicon to SiOₓ selectivity.

### SUMMARY

In one aspect, the disclosed and claimed subject matter provides etching compositions for the selective removal of silicon over silicon oxide from a microelectronic device, which includes:
A. one or more aqueous solvent;
B. one or more alkanolamine;
C. one or more quaternary ammonium hydroxide (“QAH); and
D. one or more silicon-containing compound (which also may be referred to herein as an organosilicon compound).

The alkanolamines useful in the disclosed and claimed subject matter include one or more alkanol groups and one or more amine groups. The structure for the alkanolamines useful in the disclosed and claimed subject matter has Formula I:

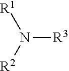

wherein R¹, R² and R³ are each independently selected from:
   (a) hydrogen,
   (b1) a C₁-C₂₀ straight chain alkyl group,
   (b2) a C₄-C₂₀ branch chain alkyl group,
   (b3) a C₃-C₂₀ cyclic alkyl group;
   (c) an unsubstituted C₂-C₂₀ alkyl ether group;
   (d) a C₁-C₂₀ alkanol group
   (e) a C₂-C₂₀ alkyl ether group substituted with an —OH group; and
wherein at least one of R¹, R² and R³ must be (d) or (e).

Alkanolamines having one alkanol group may be present in the compositions of this disclosed and claimed subject matter. Examples of alkanolamines having one alkanol group that can be used in combination with the alkanolamines having two or more alkanol groups include monoethanolamine (MEA), N-methyl ethanolamine, N-ethyl ethanolamine, N, N-dimethylethanolamine, N, N-diethylethanolamine, isopropanolamine, 2-amino-1-propanol, 3-amino-1-propanol, 2-amino-1-butanol, isobutanolamine, 2-amino-2-ethoxypropanol, 2-amino-2-ethoxyethanol.

In some embodiments, the silicon-containing compound has Formula II:

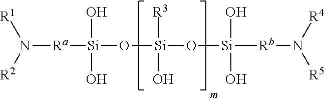

wherein:
(i) m=0-20,
(ii) each of R¹, R², R³, R⁴ and R⁵ is independently selected from the group of hydrogen, a C₁ to C₁₀ linear alkyl group, a C₁ to C₁₀ linear alkyl group substituted with fluorine, a nitrogen-containing group, an oxygen-containing group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group,

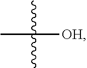 [SMILES: *O]

and
(iii) each of R^{a} and R^{b} is independently selected from a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group,

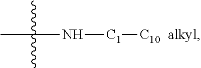

a C₁-C₁₀ alkyl substituted with

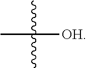 [SMILES: *O]

The embodiments of the disclosed and claimed subject matter can be used alone or in combinations with each other.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates a 3D NAND process flow for HAR vertical channel etch using double stacking.

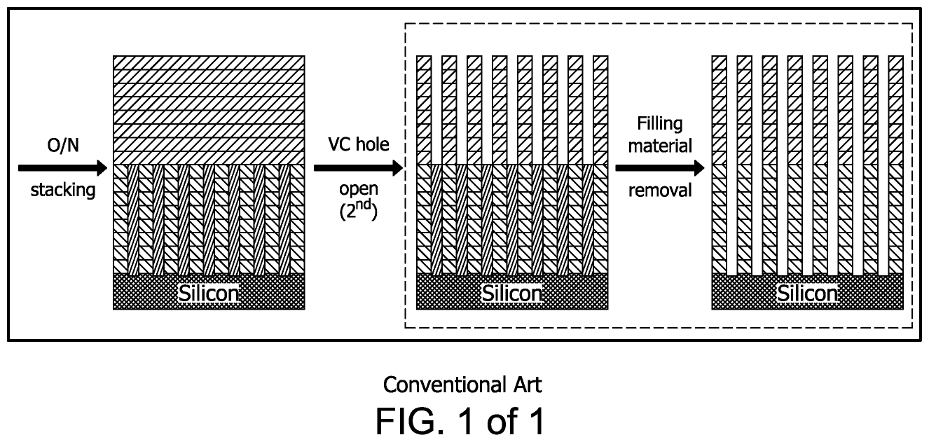

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter.

Preferred embodiments of this disclosed and claimed subject matter are described herein, including the best mode known to the inventors for carrying out the disclosed and claimed subject matter. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

The disclosed and claimed subject matter relates generally to compositions useful for the selective removal of silicon over silicon oxide from a microelectronic device having such material(s) thereon during its manufacture.

For ease of reference, “microelectronic device” or “semiconductor substrates” correspond to semiconductor wafers, flat panel displays, phase change memory devices, solar panels and other products solar substrates, photovoltaics, and including microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly. The microelectronic device or semiconductor substrates may include low-k dielectric material, barrier materials, and metals, such as, AlCu alloys, W, Ti, TiN, as well as other materials thereon.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 2 wt. %, preferably less than 1 wt. %, more preferably less than 0.5 wt. %, and most preferably less than 0.1 wt. %. “Substantially free” also includes 0.0 wt. %. The term “free of” means 0.0 wt. %.

As used herein, the terms “about” and “approximately” are each intended to correspond to ±5% of the stated value.

As used herein, “neat” refers to the weight % amount of an undiluted acid or other material. For example, the inclusion 100 g of 85% phosphoric acid constitutes 85 g of the acid and 15 grams of diluent.

In addition to known and understood representations for the attachment point of a covalent bond, the notation

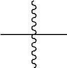

is intended to also designate the attachment point of covalent bond.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all defined weight percents of the components unless otherwise indicated are based on the total weight of the composition. Further, all weight percents unless otherwise indicated are “neat” meaning that they do not include the aqueous composition in which they are present when added to the composition. Any reference to “at least one” could be substituted with “one or more.” “At least one” and/or “one or more” includes “at least two” or “two or more” and “at least three” and “three or more” and so on.

In the broad practice of the disclosed and claimed subject matter pertains to the above-described etching composition which includes, or consists essentially of, or consists of components (A), (B) (C) and (D). In some aspect, the etching compositions can include other ingredients. In some embodiments, the etching compositions disclosed herein are formulated to be free or substantially free of at least one of the following chemical compounds:acids (inorganic and organic), oxidizers, hydrogen peroxide and other peroxides, ammonium ions, halide ions (e.g., fluoride ions, chloride ions), inorganic base, metal-containing chemicals, reducing agents, hydroxylamine, hydroxylamine derivatives, amidoxime compounds and abrasives.

In a further embodiment, the etching compositions consist essentially of (A), (B) (C) and (D) in varying concentrations. In such an embodiment, the combined amounts of (A), (B) (C) and (D) do not equal 100% by weight, and can include other ingredients that do not materially change the effectiveness of the etching compositions.

In another embodiment, the etching compositions consist of (A), (B) (C) and (D) in varying concentrations. In such an embodiment, the combined amounts of (A), (B) (C) and (D) equal or equal approximately 100% by weight but may include other small and/or trace amounts of impurities that are present in such small quantities that they do not materially change the effectiveness of the composition. For example, in one such embodiment, the etching composition can contain 2% by weight or less of impurities. In another embodiment, the etching composition can contain 1% by weight or less than of impurities. In a further embodiment, the etching composition can contain 0.05% by weight or less than of impurities.

When referring to compositions of the inventive composition described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the etching composition can contain 2% by weight or less of impurities. In another embodiment, the etching composition can contain 1% by weight or less than of impurities. In a further embodiment, the etching composition can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.9 wt %, and can include other ingredients that do not material affect the performance of the etching compositions. Otherwise, if no significant non-essential impurity component is present, it is understood that the combination of all essential constituent components will essentially add up to 100 weight %.

### Compositions

As noted above, the disclosed and claimed subject matter pertains to etching compositions which includes, or consists essentially of, or consists of (A), (B) (C) and (D). In some aspect, the etching compositions can include other ingredients.

### Component A: Aqueous Solvent

The etching compositions of the present development are aqueous-based and include water. In the disclosed and claimed subject matter, water functions in various ways such as, for example, to dissolve one or more components of the composition, as a carrier of the components, as an aid in the removal of residue, as a viscosity modifier of the composition, and as a diluent. Preferably, the water employed in the etching composition is de-ionized (DI) water.

In some embodiments, the aqueous solvent comprises water. In a further aspect of this embodiment, the aqueous solvent consists essentially of water. In a further aspect of this embodiment, the aqueous solvent consists of water.

Water is included in an amount in a range having start and end points selected from the following list of weight percents: about 1 wt % to about 65 wt % of the etching composition. In one embodiment, the compositions include about 1 wt % to about 65 wt % of water. In one embodiment, the compositions include about 5 wt % to about 65 wt % of water. In one embodiment, the compositions include about 10 wt % to about 65 wt % of water. In one embodiment, the compositions include about 15 wt % to about 65 wt % of water. In one embodiment, the compositions include about 20 wt % to about 65 wt % of water. In one embodiment, the compositions include about 25 wt % to about 65 wt % of water. In one embodiment, the compositions include about 30 wt % to about 65 wt % of water. In one embodiment, the compositions include about 35 wt % to about 65 wt % of water. In one embodiment, the compositions include about 40 wt % to about 65 wt % of water. In one embodiment, the compositions include about 45 wt % to about 65 wt % of water.

In one embodiment, the compositions include about 1 wt % to about 55 wt % of water. In one embodiment, the compositions include about 5 wt % to about 55 wt % of water. In one embodiment, the compositions include about 10 wt % to about 55 wt % of water. In one embodiment, the compositions include about 15 wt % to about 55 wt % of water. In one embodiment, the compositions include about 20 wt % to about 55 wt % of water. In one embodiment, the compositions include about 25 wt % to about 55 wt % of water. In one embodiment, the compositions include about 30 wt % to about 55 wt % of water. In one embodiment, the compositions include about 35 wt % to about 55 wt % of water. In one embodiment, the compositions include about 40 wt % to about 55 wt % of water. In one embodiment, the compositions include about 45 wt % to about 55 wt % of water.

In one embodiment, the compositions include about 30 wt % of water. In one embodiment, the compositions include about 35 wt % of water. In one embodiment, the compositions include about 40 wt % of water. In one embodiment, the compositions include about 45 wt % of water. In one embodiment, the compositions include about 50 wt % of water. In one embodiment, the compositions include about 51 wt % of water. In one embodiment, the compositions include about 52 wt % of water. In one embodiment, the compositions include about 53 wt % of water. In one embodiment, the compositions include about 54 wt % of water. In one embodiment, the compositions include about 55 wt % of water. In one embodiment, the compositions include about 56 wt % of water. In one embodiment, the compositions include about 57 wt % of water. In one embodiment, the compositions include about 58 wt % of water. In one embodiment, the compositions include about 59 wt % of water. In one embodiment, the compositions include about 60 wt % of water.

In other embodiments, water may be present in an amount defined by the following list of weight percents: 1, 5, 8, 10, 12, 15, 17, 20, 22, 25, 27, 30, 32, 35, 37, 40, 42, 45, 47, 50, 55, 60, 65, 70 and 75. Still other preferred embodiments of the disclosed and claimed subject matter could include water in an amount to achieve the desired weight percent of the other ingredients.

### Component B: Alkanolamines

As noted above, the disclosed and claimed compositions include one or more alkanolamine that include one or more alkanol groups and one or more amine groups. The structure for the alkanolamines useful in the disclosed and claimed subject matter has Formula I:

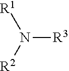

wherein R¹, R² and R³ are each independently selected from:
   (a) hydrogen,
   (b1) a C₁-C₂₀ straight chain alkyl group,
   (b2) a C₄-C₂₀ branch chain alkyl group,
   (b3) a C₃-C₂₀ cyclic alkyl group;
   (c) an unsubstituted C₂-C₂₀ alkyl ether group;
   (d) a C₁-C₂₀ alkanol group
   (e) a C₂-C₂₀ alkyl ether group substituted with an —OH group; and
wherein at least one of R¹, R² and R³ must be (d) or (e).

In one embodiment, the one or more alkanolamine includes a mixture of two or more alkanolamines. In a further aspect of this embodiment, the one or more alkanolamine includes a mixture of three or more alkanolamines. In a further aspect of this embodiment, the one or more alkanolamine, the two or more alkanolamines or the three or more alkanolamines includes one or more ether containing alkanolamine. In a further aspect of this embodiment, the one or more alkanolamine consists of a mixture of two alkanolamines. In a further aspect of this embodiment, the one or more alkanolamine consists of a mixture of three alkanolamines.

In one embodiment, (b1) is a C₁-C₁₅ straight chain alkyl group. In another embodiment, (b1) is a C₁-C₁₀ straight chain alkyl group. In another embodiment, (b1) is a C₁-C₇ straight chain alkyl group. In another embodiment, (b1) is a C₁-C₅ straight chain alkyl group. In another embodiment, (b1) is a C₁-C₄ straight chain alkyl group. In another embodiment, (b1) is a C₁-C₃ straight chain alkyl group. In another embodiment, (b1) is a C₁-C₂ straight chain alkyl group. In another embodiment, (b1) is a C₅ straight chain alkyl group. In another embodiment, (b1) is a C₄ straight chain alkyl group. In another embodiment, (b1) is a C₃ straight chain alkyl group. In another embodiment, (b1) is a C₂ straight chain alkyl group. In another embodiment, (b1) is a C₁ straight chain alkyl group.

In one embodiment, (b2) is a C₄-C₁₅ branch chain alkyl group. In another embodiment, (b2) is a C₄-C₁₀ branch chain alkyl group. In another embodiment, (b2) is a C₄-C₇ branch chain alkyl group. In another embodiment, (b2) is a C₄-C₅ branch chain alkyl group. In another embodiment, (b2) is a C₈ branch chain alkyl group. In another embodiment, (b2) is a C₇ straight chain alkyl group. In another embodiment, (b2) is a C₆ straight chain alkyl group. In another embodiment, (b2) is a C₅ straight chain alkyl group. In another embodiment, (b2) is a C₄ branch chain alkyl group.

In one embodiment, (b3) is a C₃-C₁₅ cyclic alkyl group. In another embodiment, (b3) is a C₃-C₁₀ cyclic alkyl group. In another embodiment, (b3) is a C3₁-C₇ cyclic alkyl group. In another embodiment, (b3) is a C₃-C₅ cyclic alkyl group. In another embodiment, (b3) is a C₃-C₄ cyclic alkyl group. In another embodiment, (b3) is a C₆ cyclic alkyl group. In another embodiment, (b3) is a C₅ cyclic alkyl group. In another embodiment, (b3) is a C₄ cyclic alkyl group. In another embodiment, (b3) is a C₃ cyclic alkyl group.

Alkyl ether group (c) includes (i) a C₂-C₂₀ straight chain alkyl group, (ii) a C₄-C₂₀ branch chain alkyl group and (iii) a C₃-C₂₀ cyclic alkyl group where (i), (ii) and (iii) have an oxygen atom (attached between carbons) within the respective alkyl groups. In (i), (ii) and (iii) the total number of carbons is from 2 to 20, or 2 to 15, or 2 to 10, or 2 to 7, or 2 to 5, or 2 to 4, or 2 to 3 carbons.

Alkanol group (d) includes (i) a C₁-C₂₀ straight chain alkyl group, (ii) a C₄-C₂₀ branch chain alkyl group and (iii) a C₃-C₂₀ cyclic alkyl group. In (i), (ii) and (iii) the total number of carbons is, as structurally appropriate, from 1 to 20, or 2 to 15, or 2 to 10, or 2 to 7, or 2 to 5, or 2 to 4, or 2 to 3 carbons, and further having at least one —(R)(R)— OH linked to a carbon in the alkyl group, where each R is independently H or an alkyl group (as just defined with fewer carbons than the R¹, R² or R³ group it is a part of).

Alkyl ether group substituted with an —OH group (e) includes (i) a C₂-C₂₀ straight chain alkyl group, (ii) a C₄-C₂₀ branch chain alkyl group and (iii) a C₃-C₂₀ cyclic alkyl group where (i), (ii) and (iii) have an oxygen atom (attached between carbons) within the alkyl group. In (i), (ii) and (iii) the total number of carbons is from 2 to 20, or 2 to 15, or 2 to 10, or 2 to 7, or 2 to 5, or 2 to 4, or 2 to 3 carbons, and further having at least one —(R)(R)—OH linked to a carbon in the alkyl group, where each R is independently H or an alkyl group (as just defined with fewer carbons than the R¹, R² or R³ group it is a part of).

Alkanolamines containing either (c) or (e) will be referred to as “ether containing alkanolamines.” Preferred ether containing alkanolamines have (e) an alkyl ether group further having an —OH group. For both (d) and (e), the —(R)(R)—OH linked to a carbon is preferably a terminable group, that is, both R groups are H.

In one embodiment, the composition includes alkanolamines of Formula II where R¹ and R² are hydrogen and R³ is selected from (d) and (e). In a further aspect of this embodiment, the alkanolamine consists essentially of alkanolamines of Formula II where R¹ and R² are hydrogen and R³ is selected from (d) and (e). In a further aspect of this embodiment, the alkanolamine consists of alkanolamines of Formula II where R¹ and R² are hydrogen and R³ is selected from (d) and (e).

In another embodiment, the composition includes alkanolamines of Formula II where R¹ is (a), R² is (b1), (b2) or (b3) and R³ is selected from (d) and (e). In a further aspect of this embodiment, the alkanolamine consists essentially of alkanolamines of Formula II where R¹ is (a), R² is (b1), (b2) or (b3) and R³ is selected from (d) and (e). In a further aspect of this embodiment, the alkanolamine consists of alkanolamines of Formula II where R¹ is (a), R² is (b1), (b2) or (b3) and R³ is selected from (d) and (e).

In another embodiment, the composition includes alkanolamines of Formula II where R¹ and R² are the same or different (b1), (b2) or (b3) and R³ is selected from (d) and (e). In a further aspect of this embodiment, the alkanolamine consists essentially of alkanolamines of Formula II where R¹ and R² are the same or different (b1), (b2) or (b3) and R³ is selected from (d) and (e). In a further aspect of this embodiment, the alkanolamine consists of alkanolamines of Formula II where R¹ and R² are the same or different (b1), (b2) or (b3) and R³ is selected from (d) and (e).

In another embodiment, the composition includes alkanolamines of Formula II where R¹, R² and R³ are all the same or different (d). In a further aspect of this embodiment, the alkanolamine consists essentially of alkanolamines of Formula II where R¹, R² and R³ are all the same or different (d) In a further aspect of this embodiment, the alkanolamine consists of alkanolamines of Formula II where R¹, R² and R³ are all the same or different (d).

In another embodiment, the composition includes alkanolamines of Formula II where R¹ is selected from (a), (b1), (b2) or (b3) and R² and R³ are the same or different (d). In a further aspect of this embodiment, the alkanolamine consists essentially of alkanolamines of Formula II where R¹ is selected from (a), (b1), (b2) or (b3) and R² and R³ are the same or different (d). In a further aspect of this embodiment, the alkanolamine consists of alkanolamines of Formula II where R¹ is selected from (a), (b1), (b2) or (b3) and R² and R³ are the same or different (d).

In another embodiment, the composition includes alkanolamines of Formula II where R¹ is selected from (a), (b1), (b2) or (b3) and R² and R³ are the same or different (e). In a further aspect of this embodiment, the alkanolamine consists essentially of alkanolamines of Formula II where R¹ is selected from (a), (b1), (b2) or (b3) and R² and R³ are the same or different (e). In a further aspect of this embodiment, the alkanolamine consists of alkanolamines of Formula II where R¹ is selected from (a), (b1), (b2) or (b3) and R² and R³ are the same or different (e).

As shown by the structures above, in some embodiments the alkanolamines useful in the compositions of the disclosed and claimed subject matter include two or more of the same or different (preferably the same) alkanol groups. In some embodiments, the alkanolamines include three or more of the same or different (preferably the same) alkanol groups.

Examples of alkanolamines useful in the disclosed and claimed subject matter are preferably miscible in water and include, but are not limited to, monoethanolamine (MEA), aminoethoxyethanol, methanolamine, N-methyl ethanolamine, N-ethyl ethanolamine, N, N-dimethylethanolamine, N, N-diethylethanolamine, N-methyl diethanolamine, N-ethyl diethanolamine, diethanolamine, triethanol amine (TEA), tertiarybutyldiethanol amine, isopropanolamine, 2-amino-1-propanol, 3-amino-1-propanol, 2-amino-1-butanol, isobutanolamine, 2-amino-2-ethoxypropanol, 2-amino-2-ethoxyethanol, and mixtures thereof.

Monoethanolamine (MEA), methanolamine, 2-amino-1-propanol, 3-amino-1-propanol, 2-amino-1-butanol, isobutanolamine and isopropanolamine are examples of alkanolamines where R¹ and R² are hydrogen and R³ is (d). N-methyl ethanolamine, N-ethyl ethanolamine, N, N-dimethylethanolamine, N, N-diethylethanolamine are where R¹ and R² are either H or b1 or b2, R³ is (d). Aminoethoxyethanol, 2-amino-2-ethoxypropanol and 2-amino-2-ethoxyethanol are examples of alkanolamines where R¹ and R² are hydrogen and R³ is (e). N-methyl diethanolamine, N-ethyl diethanolamine, diethanolamine, triethanolamine (TEA), tertiarybutyldiethanol amine are those alkanolamines that include two or more of the same or different (preferably the same) alkanol groups (d) as R¹, R² and/or R³. When R¹ and R² are the same alkanol groups R³ is often selected from hydrogen or a straight chained, branched or cyclic alkyl group.

In one embodiment, the one or more alkanolamines includes monoethanolamine (MEA). In one embodiment, the one or more alkanolamines consists essentially of monoethanolamine (MEA). In one embodiment, the one or more alkanolamines consists of monoethanolamine (MEA).

As noted above, in some embodiments, mixtures of two or more alkanolamines are used. Thus, in a further aspect of this embodiment, the at least one alkanolamine includes a mixture of two or more alkanolamines. In a further aspect of this embodiment, the at least one alkanolamine consists of a mixture of two alkanolamines.

As noted above, in some embodiments, mixtures of three or more alkanolamines are used. Thus, in a further aspect of this embodiment, the at least one alkanolamine includes a mixture of three or more alkanolamines. In a further aspect of this embodiment, the at least one alkanolamine consists of a mixture of three alkanolamines.

In another embodiment, (i) the at least one alkanolamine, (ii) the two or more alkanolamines or (iii) the three or more alkanolamines includes at least one ether containing alkanolamine.

In one embodiment, (i) the at least one alkanolamines, (ii) the at least two alkanolamines and (iii) the at least three alkanolamines are selected from aminoethoxyethanol, 2-amino-2-ethoxypropanol, 2-amino-2-ethoxyethanol, and mixtures thereof.

In another embodiment, (i) the at least one alkanolamines, (ii) the at least two alkanolamines and (iii) the at least three alkanolamines include monoethanolamine, isopropanolamine and 2-(2-aminoethoxy)ethanol. In a further aspect of this embodiment, the at least three alkanolamines consist essentially of monoethanolamine, the at least three alkanolamines consist of monoethanolamine, isopropanolamine and 2-(2-aminoethoxy)ethanol.

In some embodiments, the mixtures of two or more alkanolamines or three or more alkanolamines include at least one ether containing alkanolamine and at least one or two alkanolamines wherein R¹ and R² are hydrogen and R³ is (d).

In one embodiment, the compositions include about 20 wt % to about 70 wt % of the one or more alkanolamine. In one embodiment, the compositions include about 20 wt % to about 65 wt % of the one or more alkanolamine. In one embodiment, the compositions include about 35 wt % to about 60 wt % of the one or more alkanolamine. In one embodiment, the compositions include about 40 wt % to about 55 wt % of the one or more alkanolamine. In one embodiment, the compositions include about 45 wt % to about 50 wt % of the one or more alkanolamine. In one embodiment, the compositions include about 43 wt % to about 47 wt % of the one or more alkanolamine.

In one embodiment, the compositions include about 20 wt % of the one or more alkanolamine. In one embodiment, the compositions include about 25 wt % of the one or more alkanolamine. In one embodiment, the compositions include about 30 wt % of the one or more alkanolamine. In one embodiment, the compositions include about 35 wt % of the one or more alkanolamine. In one embodiment, the compositions include about 40 wt % of the one or more alkanolamine. In one embodiment, the compositions include about 41 wt % of the one or more alkanolamine. In one embodiment, the compositions include about 42 wt % of the one or more alkanolamine. In one embodiment, the compositions include about 43 wt % of the one or more alkanolamine. In one embodiment, the compositions include about 44 wt % of the one or more alkanolamine. In one embodiment, the compositions include about 45 wt % of the one or more alkanolamine. In one embodiment, the compositions include about 46 wt % of the one or more alkanolamine. In one embodiment, the compositions include about 47 wt % of the one or more alkanolamine. In one embodiment, the compositions include about 48 wt % of the one or more alkanolamine. In one embodiment, the compositions include about 49 wt % of the one or more alkanolamine. In one embodiment, the compositions include about 50 wt % of the one or more alkanolamine.

### Component C: Quaternary Ammonium Hydroxide

As noted above, the one or more base component can include one or more quaternary ammonium hydroxide. Suitable quaternary ammonium hydroxides include, but are not limited to, tetramethylammonium hydroxide (TMAH), tetraethylammonium hydroxide (TEAH), tetrapropylammonium hydroxide (TPAH), tetrabutylammonium hydroxide (TBAH), ethyltrimethylammonium hydroxide (ETMAH), benzyltrimethylammonium hydroxide (BTMAH), choline hydroxide, tris-(hydroxyethyl)methyl ammonium hydroxide and dimethyldipropylammonium hydroxide (DMDPAH). In some embodiments, TEAH is preferentially included. In such embodiments, the TEAH is used as an aqueous solution, for example a 35 wt % aqueous solution. In other embodiments, DMDPAH is preferentially included. In such embodiments, the DMDPAH is used as 20 wt % solution in propylene glycol. In some embodiments, ETMAH is preferentially included. In such embodiments, the ETMAH is used as an aqueous solution, for example a 20 wt % aqueous solution. In some embodiments, TMAH is preferentially included. In such embodiments, the TMAH is used as an aqueous solution, for example a 25 wt % aqueous solution. In some embodiments, the solutions are free from TMAH.

The quaternary ammonium hydroxide may be present in any neat amounts ranging from about 0.1 wt % to about 20 wt %, 1 wt % to about 15 wt %, or from about 1 wt % to about 14 wt %, or from about 1 wt % to about 13 wt % or from about 1 wt % to about 12 wt %, or from about 1 wt % to about 11 wt %, or from about 1 wt % to about 10 wt %, or from about 1 wt % to about 9 wt %, or from about 1 wt % to about 8 wt %, or from about 1 wt % to about 7 wt %, or from about 1 wt % to about 6 wt %, or from about 1 wt % to about 5 wt %, or from about 1 wt % to about 4 wt %, or from about 1 wt % to about 3 wt %, or from about 1 wt % to about 2 wt %, or from about 0.1 wt % to about 0.9 wt %, or from about 0.4 wt % to about 0.5 wt %, or from about 0.1 wt % to about 0.2 wt % of the composition. More preferably, the quaternary ammonium hydroxide is present, but in an amount not greater than about 20 wt %. In certain preferred compositions, the quaternary ammonium hydroxide is present at about 8 wt % to 15 wt %. In certain preferred compositions, the quaternary ammonium hydroxide is present at about 8 wt % to about 13 wt %. In certain preferred compositions, the quaternary ammonium hydroxide is present at about 10 wt % to about 15 wt %. In certain preferred compositions, the quaternary ammonium hydroxide is present at about 0.1 wt % to about 1 wt %. In certain preferred compositions, the quaternary ammonium hydroxide is present at about 0.4 wt % to about 2 wt %. In certain preferred compositions, the quaternary ammonium hydroxide is present at about 0.4 wt % to about 1 wt %. In certain preferred compositions, the quaternary ammonium hydroxide is present at about 0.1 wt % to about 0.5 wt %.

In one embodiment, the solutions include about 0.5 wt % to 5 wt % of neat TEAH. In a further aspect of this embodiment, the solutions include about 1 wt % to about 4 wt % of neat TEAH. In another aspect of this embodiment, the solutions include about 1.5 wt % to about 3.5 wt % of neat TEAH. In another aspect of this embodiment, the solutions include about 2 wt % to about 3 wt % of neat TEAH. In another aspect of this embodiment, the solutions include about 0.5 wt % of neat TEAH. In another aspect of this embodiment, the solutions include about 1 wt % of neat TEAH. In another aspect of this embodiment, the solutions include about 1.5 wt % of neat TEAH. In another aspect of this embodiment, the solutions include about 2 wt % of neat TEAH. In another aspect of this embodiment, the solutions include about 2.5 wt % of neat TEAH. In another aspect of this embodiment, the solutions include about 3 wt % of neat TEAH. In another aspect of this embodiment, the solutions include about 3.5 wt % of neat TEAH. In another aspect of this embodiment, the solutions include about 4 wt % of neat TEAH. In another aspect of this embodiment, the solutions include about 5 wt % of neat TEAH.

In one embodiment, the solutions include about 1 wt % to 5 wt % of neat DMDPAH. In a further aspect of this embodiment, the solutions include about 1 wt % to about 4.5 wt % of neat DMDPAH. In another aspect of this embodiment, the solutions include about 1.5 wt % to about 4 wt % of neat DMDPAH. In another aspect of this embodiment, the solutions include about 2 wt % to about 3.5 wt % of neat DMDPAH. In another aspect of this embodiment, the solutions include about 2 wt % to about 3 wt % of neat DMDPAH. In another aspect of this embodiment, the solutions include about 2.1 wt % of neat DMDPAH. In another aspect of this embodiment, the solutions include about 2.2 wt % of neat DMDPAH. In another aspect of this embodiment, the solutions include about 2.3 wt % of neat DMDPAH. In another aspect of this embodiment, the solutions include about 2.4 wt % of neat DMDPAH. In another aspect of this embodiment, the solutions include about 2.6 wt % of neat DMDPAH. In another aspect of this embodiment, the solutions include about 2.8 wt % of neat DMDPAH. In another aspect of this embodiment, the solutions include about 3 wt % of neat DMDPAH.

In one embodiment, the solutions include about 0.5 wt % to 5 wt % of neat choline hydroxide. In a further aspect of this embodiment, the solutions include about 1 wt % to about 4 wt % of neat choline hydroxide. In another aspect of this embodiment, the solutions include about 1.5 wt % to about 3.5 wt % of neat choline hydroxide. In another aspect of this embodiment, the solutions include about 2 wt % to about 3 wt % of neat choline hydroxide. In another aspect of this embodiment, the solutions include about 0.5 wt % of neat choline hydroxide. In another aspect of this embodiment, the solutions include about 1 wt % of neat choline hydroxide. In another aspect of this embodiment, the solutions include about 1.5 wt % of neat choline hydroxide. In another aspect of this embodiment, the solutions include about 2 wt % of neat choline hydroxide. In another aspect of this embodiment, the solutions include about 2.5 wt % of neat choline hydroxide. In another aspect of this embodiment, the solutions include about 3 wt % of neat choline hydroxide. In another aspect of this embodiment, the solutions include about 3.5 wt % of neat choline hydroxide. In another aspect of this embodiment, the solutions include about 4 wt % of neat choline hydroxide. In another aspect of this embodiment, the solutions include about 5 wt % of neat choline hydroxide.

In one embodiment, the solutions include about 0.1 wt % to about 3 wt % of neat ETMAH. In one embodiment, the solutions include about 0.1 wt % to about 2.5 wt % of neat ETMAH. In one embodiment, the solutions include about 0.1 wt % to about 2 wt % of neat ETMAH. In one embodiment, the solutions include about 0.1 wt % to about 1.5 wt % of neat ETMAH. In one embodiment, the solutions include about 0.1 wt % to about 1 wt % of neat ETMAH. In one embodiment, the solutions include about 0.1 wt % to about 0.5 wt % of neat ETMAH. In one embodiment, the solutions include about 0.2 wt % to about 2 wt % of neat ETMAH. In one embodiment, the solutions include about 0.2 wt % to about 1.5 wt % of neat ETMAH. In one embodiment, the solutions include about 0.2 wt % to about 1 wt % of neat ETMAH. In one embodiment, the solutions include about 0.2 wt % to about 0.5 wt % of neat ETMAH. In another aspect of this embodiment, the solutions include about 0.1 wt % of neat ETMAH. In another aspect of this embodiment, the solutions include about 0.2 wt % of neat ETMAH. In another aspect of this embodiment, the solutions include about 0.3 wt % of neat ETMAH. In another aspect of this embodiment, the solutions include about 0.4 wt % of neat ETMAH. In another aspect of this embodiment, the solutions include about 0.5 wt % of neat ETMAH. In another aspect of this embodiment, the solutions include about 0.6 wt % of neat ETMAH. In another aspect of this embodiment, the solutions include about 0.7 wt % of neat ETMAH. In another aspect of this embodiment, the solutions include about 0.8 wt % of neat ETMAH. In another aspect of this embodiment, the solutions include about 0.9 wt % of neat ETMAH. In another aspect of this embodiment, the solutions include about 1.0 wt % of neat ETMAH. In another aspect of this embodiment, the solutions include about 1.1 wt % of neat ETMAH. In another aspect of this embodiment, the solutions include about 1.2 wt % of neat ETMAH. In another aspect of this embodiment, the solutions include about 1.3 wt % of neat ETMAH. In another aspect of this embodiment, the solutions include about 1.4 wt % of neat ETMAH. In another aspect of this embodiment, the solutions include about 1.5 wt % of neat ETMAH. In another aspect of this embodiment, the solutions include about 1.6 wt % of neat ETMAH. In another aspect of this embodiment, the solutions include about 1.7 wt % of neat ETMAH. In another aspect of this embodiment, the solutions include about 1.8 wt % of neat ETMAH. In another aspect of this embodiment, the solutions include about 1.9 wt % of neat ETMAH. In another aspect of this embodiment, the solutions include about 2.0 wt % of neat ETMAH.

In one embodiment, the solutions include about 0.1 wt % to about 3 wt % of neat TMAH. In one embodiment, the solutions include about 0.1 wt % to about 2.5 wt % of neat TMAH. In one embodiment, the solutions include about 0.1 wt % to about 2 wt % of neat TMAH. In one embodiment, the solutions include about 0.1 wt % to about 1.5 wt % of neat TMAH. In one embodiment, the solutions include about 0.1 wt % to about 1 wt % of neat TMAH. In one embodiment, the solutions include about 0.1 wt % to about 0.5 wt % of neat TMAH. In one embodiment, the solutions include about 0.2 wt % to about 2 wt % of neat TMAH. In one embodiment, the solutions include about 0.2 wt % to about 1.5 wt % of neat TMAH. In one embodiment, the solutions include about 0.2 wt % to about 1 wt % of neat TMAH. In one embodiment, the solutions include about 0.2 wt % to about 0.5 wt % of neat TMAH. In another aspect of this embodiment, the solutions include about 0.1 wt % of neat TMAH. In another aspect of this embodiment, the solutions include about 0.2 wt % of neat TMAH. In another aspect of this embodiment, the solutions include about 0.3 wt % of neat TMAH. In another aspect of this embodiment, the solutions include about 0.4 wt % of neat TMAH. In another aspect of this embodiment, the solutions include about 0.5 wt % of neat TMAH. In another aspect of this embodiment, the solutions include about 0.6 wt % of neat TMAH. In another aspect of this embodiment, the solutions include about 0.7 wt % of neat TMAH. In another aspect of this embodiment, the solutions include about 0.8 wt % of neat TMAH. In another aspect of this embodiment, the solutions include about 0.9 wt % of neat TMAH. In another aspect of this embodiment, the solutions include about 1.0 wt % of neat TMAH. In another aspect of this embodiment, the solutions include about 1.1 wt % of neat TMAH. In another aspect of this embodiment, the solutions include about 1.2 wt % of neat TMAH. In another aspect of this embodiment, the solutions include about 1.3 wt % of neat TMAH. In another aspect of this embodiment, the solutions include about 1.4 wt % of neat TMAH. In another aspect of this embodiment, the solutions include about 1.5 wt % of neat TMAH. In another aspect of this embodiment, the solutions include about 1.6 wt % of neat TMAH. In another aspect of this embodiment, the solutions include about 1.7 wt % of neat TMAH. In another aspect of this embodiment, the solutions include about 1.8 wt % of neat TMAH. In another aspect of this embodiment, the solutions include about 1.9 wt % of neat TMAH. In another aspect of this embodiment, the solutions include about 2.0 wt % of neat TMAH. In another aspect of this embodiment, the solutions include about 2.1 wt % of neat TMAH. In another aspect of this embodiment, the solutions include about 2.2 wt % of neat TMAH. In another aspect of this embodiment, the solutions include about 2.3 wt % of neat TMAH. In another aspect of this embodiment, the solutions include about 2.4 wt % of neat TMAH. In another aspect of this embodiment, the solutions include about 2.5 wt % of neat TMAH. In one embodiment, the solutions are substantially free of neat TMAH. In one embodiment, the solutions are free of neat TMAH.

### Component D: Silicon-Containing Compound

As noted above, the silicon-containing compound has Formula II:

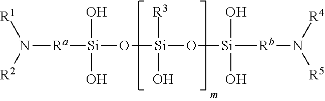

wherein:
(i) m=0-20,
(ii) each of R¹, R², R³, R⁴ and R⁵ is independently selected from the group of hydrogen, a C₁ to C₁₀ linear alkyl group, a C₁ to C₁₀ linear alkyl group substituted with fluorine, a nitrogen-containing group, an oxygen-containing group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group, - [symbol] -OH, and
(iii) each of R^{a} and R^{b} is independently selected from a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group, - [symbol] -NH—C₁-C₁₀ alkyl, a C₁-C₁₀ alkyl substituted with - [symbol] -OH.

In some embodiments of the etching composition that include the silicon-containing compound of Formula I, each of R¹, R², R³, R⁴ and R⁵ is the same. In a further aspect of this embodiment, each of R¹, R², R³, R⁴ and R⁵ is hydrogen.

In some embodiments of the etching composition that include the silicon-containing compound of Formula I, at least one of R¹, R², R³, R⁴ and R⁵ is something other than hydrogen.

In some embodiments of the etching composition that include the silicon-containing compound of Formula I, m=0-20. In a further aspect of this embodiment, m is 0. In a further aspect of this embodiment, m is 1. In a further aspect of this embodiment, m is 2. In a further aspect of this embodiment, m is 3. In a further aspect of this embodiment, m is 4. In a further aspect of this embodiment, m is 5. In a further aspect of this embodiment, m is 6. In a further aspect of this embodiment, m is 7. In a further aspect of this embodiment, m is 8. In a further aspect of this embodiment, m is 9. In a further aspect of this embodiment, m is 10. In a further aspect of this embodiment, m is 11. In a further aspect of this embodiment, m is 12. In a further aspect of this embodiment, m is 13. In a further aspect of this embodiment, m is 14. In a further aspect of this embodiment, m is 15. In a further aspect of this embodiment, m is 16. In a further aspect of this embodiment, m is 17. In a further aspect of this embodiment, m is 18. In a further aspect of this embodiment, m is 19. In a further aspect of this embodiment, m is 20.

In one embodiment, the solutions include about 0.15 wt % to about 2 wt % of one or more neat silicon-containing compound of Formula I. In one embodiment, the solutions include about 0.2 wt % to about 1.75 wt % of one or more neat silicon-containing compound of Formula I. In one embodiment, the solutions include about 0.25 wt % to about 1.5 wt % of one or more neat silicon-containing compound of Formula I. In one embodiment, the solutions include about 0.3 wt % to about 1.25 wt % of one or more neat silicon-containing compound of Formula I. In one embodiment, the solutions include about 0.35 wt % to about 1.0 wt % of one or more neat silicon-containing compound of Formula I. In one embodiment, the solutions include about 0.4 wt % to about 0.95 wt % of one or more neat silicon-containing compound of Formula I. In one embodiment, the solutions include about 0.45 wt % to about 0.9 wt % of one or more neat silicon-containing compound of Formula I. In one embodiment, the solutions include about 0.5 wt % to about 0.85 wt % of one or more neat silicon-containing compound of Formula I. In one embodiment, the solutions include about 0.55 wt % to about 0.8 wt % of one or more neat silicon-containing compound of Formula I. In one embodiment, the solutions include about 0.6 wt % to about 0.75 wt % of one or more neat silicon-containing compound of Formula I.

In one embodiment, the solutions include about 0.15 wt % of one or more neat silicon-containing compound of Formula I. In one embodiment, the solutions include about 0.25 wt % of one or more neat silicon-containing compound of Formula I. In one embodiment, the solutions include about 0.325 wt % of one or more neat silicon-containing compound of Formula I. In one embodiment, the solutions include about 0.4875 wt % of one or more neat silicon-containing compound of Formula I. In one embodiment, the solutions include about 0.5 wt % of one or more neat silicon-containing compound of Formula I. In one embodiment, the solutions include about 0.65 wt % of one or more neat silicon-containing compound of Formula I. In one embodiment, the solutions include about 0.75 wt % of one or more neat silicon-containing compound of Formula I. In one embodiment, the solutions include about 0.8 wt % of one or more neat silicon-containing compound of Formula I. In one embodiment, the solutions include about 0.9 wt % of one or more neat silicon-containing compound of Formula I. In one embodiment, the solutions include about 1.0 wt % of one or more neat silicon-containing compound of Formula I. In one embodiment, the solutions include about 1.1 wt % of one or more neat silicon-containing compound of Formula I. In one embodiment, the solutions include about 1.2 wt % of one or more neat silicon-containing compound of Formula I. In one embodiment, the solutions include about 1.3 wt % of one or more neat silicon-containing compound of Formula I. In one embodiment, the solutions include about 1.4 wt % of one or more neat silicon-containing compound of Formula I. In one embodiment, the solutions include about 1.5 wt % of one or more neat silicon-containing compound of Formula I. In one embodiment, the solutions include about 1.6 wt % of one or more neat silicon-containing compound of Formula I. In one embodiment, the solutions include about 1.7 wt % of one or more neat silicon-containing compound of Formula I. In one embodiment, the solutions include about 1.8 wt % of one or more neat silicon-containing compound of Formula I. In one embodiment, the solutions include about 1.9 wt % of one or more neat silicon-containing compound of Formula I. In one embodiment, the solutions include about 2.0 wt % of one or more neat silicon-containing compound of Formula I.

In some embodiments, the etching composition includes the silicon-containing compound of Formula I where (i) each of R^{a} and R^{b} is

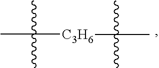

(ii) each of R¹, R², R⁴ and R⁵ is

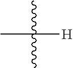 [SMILES: *[H]]

and (iii) m=0.

In some embodiments, the etching composition includes the silicon-containing compound of Formula I where (i) each of R^{a} and R^{b} is

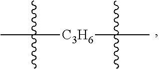

(ii) each of R¹, R², R⁴ and R⁵ is

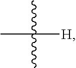

(iii) m=0 and (iv) R³=

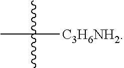

In some embodiments, the etching composition includes the silicon-containing compound of Formula I where (i) each of R^{a} and R^{b} is

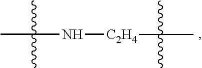

(ii) each of R¹, R², R³, R⁴ and R⁵ is

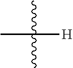 [SMILES: *[H]]

and (ii) m=0.

In some embodiments, the etching composition includes the silicon-containing compound of Formula I having the structure:

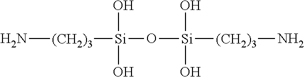

(hereinafter “Si Compound 1”).

In one embodiment, the solutions include about 0.15 wt % to about 2.0 wt % of neat Si Compound 1. In one embodiment, the solutions include about 0.2 wt % to about 1.75 wt % of neat Si Compound 1. In one embodiment, the solutions include about 0.25 wt % to about 1.5 wt % of neat Si Compound 1. In one embodiment, the solutions include about 0.3 wt % to about 1.25 wt % of neat Si Compound 1. In one embodiment, the solutions include about 0.35 wt % to about 1.0 wt % of neat Si Compound 1. In one embodiment, the solutions include about 0.4 wt % to about 0.95 wt % of neat Si Compound 1. In one embodiment, the solutions include about 0.05 wt % to about 0.9 wt % of neat Si Compound 1. In one embodiment, the solutions include about 0.5 wt % to about 0.85 wt % of neat Si Compound 1. In one embodiment, the solutions include about 0.55 wt % to about 0.8 wt % of neat Si Compound 1. In one embodiment, the solutions include about 0.6 wt % to about 0.75 wt % of neat Si Compound 1.

In one embodiment, the solutions include about 0.15 wt % of neat Si Compound 1. In one embodiment, the solutions include about 0.25 wt % of neat Si Compound 1. In one embodiment, the solutions include about 0.325 wt % of neat Si Compound 1. In one embodiment, the solutions include about 0.5 wt % of neat Si Compound 1. In one embodiment, the solutions include about 0.65 wt % of neat Si Compound 1. In one embodiment, the solutions include about 0.75 wt % of neat Si Compound 1. In one embodiment, the solutions include about 0.8 wt % of neat Si Compound 1. In one embodiment, the solutions include about 0.9 wt % of neat Si Compound 1. In one embodiment, the solutions include about 1.0 wt % of neat Si Compound 1. In one embodiment, the solutions include about 1.1 wt % of neat Si Compound 1. In one embodiment, the solutions include about 1.2 wt % of neat Si Compound 1. In one embodiment, the solutions include about 1.3 wt % of neat Si Compound 1. In one embodiment, the solutions include about 1.4 wt % of neat Si Compound 1. In one embodiment, the solutions include about 1.5 wt % of neat Si Compound 1. In one embodiment, the solutions include about 1.6 wt % of neat Si Compound 1. In one embodiment, the solutions include about 1.7 wt % of neat Si Compound 1. In one embodiment, the solutions include about 1.8 wt % of neat Si Compound 1. In one embodiment, the solutions include about 1.9 wt % of neat Si Compound 1. In one embodiment, the solutions include about 2.0 wt % of neat Si Compound 1.

### Exemplary Embodiments of Etching Compositions

The following are exemplary embodiments of etching compositions suitable for the selective removal of silicon over silicon oxide from a microelectronic device, which includes:
A. one or more aqueous solvent;
B. one or more alkanolamine;
C. one or more quaternary ammonium hydroxide; and
D. one or more silicon-containing compound.

In one embodiment, the etching composition includes:
A. water;
B. one or more alkanolamine of Formula I:

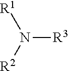

wherein R¹, R² and R³ are each independently selected from:
   (a) hydrogen,
   (b1) a C₁-C₂₀ straight chain alkyl group,
   (b2) a C₄-C₂₀ branch chain alkyl group,
   (b3) a C₃-C₂₀ cyclic alkyl group;
   (c) an unsubstituted C₂-C₂₀ alkyl ether group;
   (d) a C₁-C₂₀ alkanol group
(e) a C₂-C₂₀ alkyl ether group substituted with an —OH group, and wherein at least one of R¹, R² and R³ must be (d) or (e);
C. one or more quaternary ammonium hydroxide; and
D. one or more silicon-containing compound of Formula II:

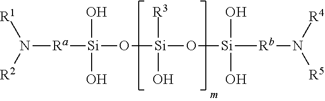

wherein:
(i) m=0-20,
(ii) each of R¹, R², R³, R⁴ and R⁵ is independently selected from the group of hydrogen, a C₁ to C₁₀ linear alkyl group, a C₁ to C₁₀ linear alkyl group substituted with fluorine, a nitrogen-containing group, an oxygen-containing group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group, - [symbol] -OH, and
(iii) each of R^{a} and R^{b} is independently selected from a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group, - [symbol] -NH—C₁-C₁₀ alkyl, a C₁-C₁₀ alkyl substituted with - [symbol] -OH.

In one embodiment, the etching composition includes:
A. water;
B. monoethanolamine (MEA);
C. ethyltrimethylammonium hydroxide (ETMAH); and
D. Si Compound 1.

In one embodiment, the etching composition includes:
A. about 35 wt % to about 60 wt % of water;
B. about 20.0 to about 70.0 wt % of monoethanolamine (MEA);
C. about 0.1 wt % to about 3 wt % ethyltrimethylammonium hydroxide (ETMAH); and
D. about 0.15 wt % to about 2.0 wt % of neat Si Compound 1.

### Other Ingredients

The etching composition, including those exemplified above, can include other optional components as described below.

### Additional Silicon-Containing Compound

In some embodiments, the mixture can include an additional silicon-containing compound(s) other than those of Formula 1. Such additional silicon-containing compound(s) can be is one or more of alkylsilsesquioxanes, vinylsilsesquioxane, carboxylic acid alkylsilsesquioxane and alkyleneglycol alkylsilsesquioxane.

### Hydroxyl Group-Containing Water-Miscible Solvent

In some embodiments, the mixture can include a hydroxyl group-containing water-miscible solvent. The hydroxyl group-containing water-miscible solvent functions primarily to protect the silicon oxide such that the silicon is etched preferentially and selectively.

Classes of suitable hydroxyl group-containing water-miscible solvents include, but are not limited to, alkane diols and polyols (including, but not limited to, alkylene glycols), glycols, alkoxyalcohols (including but not limited to glycol monoethers), saturated aliphatic monohydric alcohols, unsaturated non-aromatic monohydric alcohols, and low molecular weight alcohols containing a ring structure.

Examples of suitable water soluble alkane diols and polyols such as (C₂-C₂₀) alkanediols and (C₃-C₂₀) alkanetriols including, but are not limited to, 2-methyl-1,3-propanediol, 1,3-propanediol, 2,2-dimethyl-1,3-propanediol, 1,4-butanediol, 1,3-butanediol, 1,2-butanediol, 2,3-butanediol, and pinacol.

Examples of suitable water soluble alkylene glycols include, but are not limited to, ethylene glycol, propylene glycol, diethylene glycol, glycerol, dipropylene glycol, triethylene glycol and tetraethyleneglycol.

Examples of suitable water soluble alkoxyalcohols include, but are not limited to, 3-methoxy-3-methyl-1-butanol, 3-methoxy-1-butanol, 1-methoxy-2-butanol, and water soluble glycol monoethers.

Examples of suitable water soluble glycol monoethers include, but are not limited to, ethylene glycol monomethyl ether, ethylene glycol monoethyl ether, ethylene glycol mono n-propyl ether, ethylene glycol monoisopropyl ether, ethylene glycol mono n-butyl ether, diethylene glycol monomethyl ether, diethylene glycol monoethyl ether, diethylene glycol monobutylether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether and ethylene glycol monobenzyl ether, diethylene glycol monobenzyl ether, and mixtures thereof.

Examples of suitable water soluble saturated aliphatic monohydric alcohols include, but are not limited to methanol, ethanol, n-propyl alcohol, isopropyl alcohol, 1-butanol, 2-butanol, isobutyl alcohol, tert-butyl alcohol, 2-pentanol, t-pentyl alcohol, 1-hexanol, and mixtures thereof.

Examples of suitable water soluble unsaturated non-aromatic monohydric alcohols include, but are not limited to allyl alcohol, propargyl alcohol, 2-butenyl alcohol, 3-butenyl alcohol, 4-penten-2-ol, and mixtures thereof.

Examples of suitable water soluble, low molecular weight alcohols containing a ring structure include, but are not limited to, alpha-terpineol, tetrahydrofurfuryl alcohol, furfuryl alcohol, 1,3-cyclopentanediol, and mixtures thereof.

In some embodiments, the amount of hydroxyl group-containing water-miscible solvent constitutes from about 1.0% to about 30% by weight of the composition. Preferably, when employed, the hydroxyl group-containing water-miscible solvent constitutes from about 5% to about 15% by weight of the composition.

In some embodiments, the compositions of the disclosed and claimed subject matter will be free or substantially free of hydroxyl group-containing water-miscible solvent or any or all of the hydroxyl group-containing water-miscible solvents listed above.

### Silicic Acid

In some embodiments, the mixture can include a silicic acid. If employed, the silicic acid aids in protecting the silicon oxide and increasing the selectivity of the silicon etch.

In some embodiments, the amount of silicic acid will constitute from about 0.001% to about 5.0% by weight of the composition and, preferably, from about 0.01% by weight to about 2.0% by weight. In other embodiments, the silicic acid constitutes from about 0.02% to about 0.08% by weight of the composition.

In some embodiments, the compositions of the disclosed and claimed subject matter will be free of or substantially free of added silicic acid.

### Surfactants

In some embodiments, the mixture can include at least one water-soluble nonionic surfactant. Surfactants serve to aid in the removal of residue.

Examples of the water-soluble nonionic surfactants include polyoxyethylene lauryl ether, polyoxyethylene cetyl ether, polyoxyethylene steary ether, polyoxyethylene oleyl ether, polyoxyethylene higher alcohol ether, polyoxyethylene octyl phenyl ether, polyoxyethylene nonyl phenyl ether, polyoxyethylene derivatives, polyoxyethylene sorbitan monolaurate, polyoxyethylene sorbitan monopalmitate, polyoxyethylene sorbitan monostearate, polyoxyethylene sorbitan tristearate, polyoxyethylene sorbitan monooleate, polyoxyethylene sorbitan trioleate, polyoxyethylene sorbit tetraoleate, polyethylene glycol monolaurate, polyethylene glycol monostearate, polyethylene glycol distearate, polyethylene glycol monooleate, polyoxyethylene alkylamine, polyoxyethylene hardened castor oil, alkylalkanolamide and mixtures thereof.

In some embodiments, the amount of the surfactant will include from about 0.001 wt. % to about 5 wt. % of the composition, preferably from about 0.01 wt. % to about 2.5 wt. % and, most preferably, from about 0.1 wt. % to about 1.0 wt. % of the composition.

In some embodiments, the compositions of the disclosed and claimed subject matter will be free of or substantially free of surfactants.

In some embodiment, the compositions are substantially free or free of metal hydroxides, added metals, halide containing compounds, TEOS, silyl phosphate compounds and silanes and silanols that do not include repeating monomers.

### Methods of Manufacture

The disclosed and claimed subject matter further includes method of manufacturing the etching compositions described and claimed herein.

In one embodiment, the method for forming the etching composition includes combining: A. one or more aqueous solvent;
B. one or more alkanolamine;
C. one or more quaternary ammonium hydroxide; and
D. one or more silicon-containing compound.

In one embodiment, the method for forming the etching composition includes combining: A. water;
B. one or more alkanolamine of Formula I:

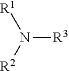

wherein R¹, R² and R³ are each independently selected from:
   (a) hydrogen,
   (b1) a C₁-C₂₀ straight chain alkyl group,
   (b2) a C₄-C₂₀ branch chain alkyl group,
   (b3) a C₃-C₂₀ cyclic alkyl group;
   (c) an unsubstituted C₂-C₂₀ alkyl ether group;
   (d) a C₁-C₂₀ alkanol group
(e) a C₂-C₂₀ alkyl ether group substituted with an —OH group, and wherein at least one of R¹, R² and R³ must be (d) or (e);
C. one or more quaternary ammonium hydroxide; and
D. one or more silicon-containing compound of Formula II:

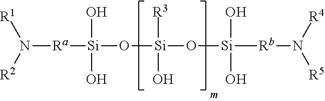

wherein:
(i) m=0-20,
(ii) each of R¹, R², R³, R⁴ and R⁵ is independently selected from the group of hydrogen, a C₁ to C₁₀ linear alkyl group, a C₁ to C₁₀ linear alkyl group substituted with fluorine, a nitrogen-containing group, an oxygen-containing group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group,

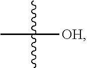 [SMILES: *O]

(iii) each of R^{a} and R^{b} is independently selected from a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group,

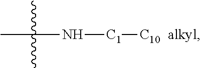

a C₁-C₁₀ alkyl substituted with

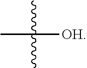 [SMILES: *O]

In one embodiment, the method for forming the etching composition includes combining: A. water;
B. monoethanolamine (MEA);
C. ethyltrimethylammonium hydroxide (ETMAH); and
D. Si Compound 1.

In one embodiment, the method for forming the etching composition includes combining: A. about 35 wt % to about 60 wt % of water;
B. about 20.0 to about 70.0 wt % of monoethanolamine (MEA);
C. about 0.1 wt % to about 3 wt % ethyltrimethylammonium hydroxide (ETMAH); and
D. about 0.015 wt % to about 0.2 wt % of neat Si Compound 1.

### Methods of Use

The disclosed and claimed subject matter further includes a method of using the disclosed and claimed etching compositions to selectively remove a silicon film while minimizing the etch rate of an oxide film and to a method for fabricating a semiconductor, which includes an etching process employing the disclosed and claimed etching compositions.

In one embodiment, the method includes the steps of:
a. contacting the composite semiconductor device including a silicon film with one or more of the etching compositions disclosed and/or claimed herein, and
b. rinsing the composite semiconductor device after the silicon film is at least partially removed.
   In as further aspect of this embodiment, the contacting step is performed at a temperature of about 25° C. to about 90° C.

In a further embodiment, the method can include c. a drying step.

In the described methods, “at least partially removed” means removal of at least 90% of the material, preferably at least 95% removal. Most preferably, at least 99% removal using the compositions of the present development. “Si Oxide Compatibility” means less than 10% film loss.

In a further embodiment, the method can include a pre-treatment step which includes contacting (e.g., by dipping or spraying) the substrate with dilute hydrofluoric acid (“DHF”) (1:100 HF: water). Further damage due to the dHF pretreatment step could be minimized by decreased agitation when treating with the compositions of the disclosed and claimed subject matter and decreased time between pretreatment and contact with the compositions of the disclosed and claimed subject matter.

In some embodiments, the contacting step can be carried out by any suitable means such as, for example, immersion, spray, or via a single wafer process.

In some embodiments, the temperature of the composition during the contacting step is preferably from about 25° C. to about 90° C. In a further aspect, the temperature is about 40° C. to about 80° C. In a further aspect, the temperature of the composition during the contacting step is about 75° C.

In some embodiments, the etch selectivity of silicon over silicon oxide of the disclosed and claimed subject etch compositions is between about 300 and about 5000. In some embodiments, the etch selectivity of silicon over silicon oxide of the disclosed and claimed subject etch compositions is between about 500 and about 4000. In some embodiments, the etch selectivity of silicon over silicon oxide of the disclosed and claimed subject etch compositions is between about 1000 and about 3000. In some embodiments, the etch selectivity of silicon over silicon oxide of the disclosed and claimed subject etch compositions is between about 1000 and about 2000. In some embodiments, the etch selectivity of silicon over silicon oxide of the disclosed and claimed subject etch compositions is between about 1000 and about 1500. In some embodiments, the etch selectivity of silicon over silicon oxide of the disclosed and claimed subject etch compositions is between about 500 and about 1500. In some embodiments, the etch selectivity of silicon over silicon oxide of the disclosed and claimed subject etch compositions is between about 500 and about 2000.

In some embodiments, the etch selectivity of silicon over silicon oxide of the disclosed and claimed subject etch compositions is over about 300. In a further aspect, the etch selectivity of silicon over silicon oxide of the disclosed and claimed subject etch compositions is over about 500. In a further aspect, the etch selectivity of silicon over silicon oxide of the disclosed and claimed subject etch compositions is over about 1000. In a further aspect, the etch selectivity of silicon over silicon oxide of the disclosed and claimed subject etch compositions is over about 1250. In a further aspect, the etch selectivity of silicon over silicon oxide of the disclosed and claimed subject etch compositions is over about 1500. In a further aspect, the etch selectivity of silicon over silicon oxide of the disclosed and claimed subject etch compositions is over about 2000. In a further aspect, the etch selectivity of silicon over silicon oxide of the disclosed and claimed subject etch compositions is over about 2500. In a further aspect, the etch selectivity of silicon over silicon oxide of the disclosed and claimed subject etch compositions is over about 3000. In a further aspect, the etch selectivity of silicon over silicon oxide of the disclosed and claimed subject etch compositions is over about 3500. In a further aspect, the etch selectivity of silicon over silicon oxide of the disclosed and claimed subject etch compositions is over about 4000. In a further aspect, the etch selectivity of silicon over silicon oxide of the disclosed and claimed subject etch compositions is over about 4500. In a further aspect, the etch selectivity of silicon over silicon oxide of the disclosed and claimed subject etch compositions is over about 5000.

In some embodiments, the silicon oxide etch is less than 1 Å/min. In a further aspect the silicon oxide etch is less than 0.5 Å/min. In a further aspect, the silicon oxide etch is less than 0.01 Å/min.

In some embodiments, the rinsing step c. is carried out by any suitable means, for example, rinsing the substrate with de-ionized water by immersion or spray techniques. In another aspect, the rinsing step is carried out employing a mixture of de-ionized water and a water-miscible organic solvent such as, for example, isopropyl alcohol.

In some embodiments, the drying step is carried out by any suitable means, for example, isopropyl alcohol (IPA) vapor drying, heat, or by centripetal force.

### Examples

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All ingredients used herein are commercially available.

In the Examples, the following silicon-containing compounds were used:

| Ref. | Material | CAS No. |
|---|---|---|
| Si Compound 1 (32.5% or 45%) | 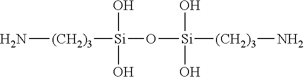 | — |
| MEA | Monoethanolamine | 141-43-5 |
| ETMAH (20%) | Ethyltrimethylammonium Hydroxide | 30382-83-3 |
| TMAH (25% ) | Tetramethylammonium Hydroxide | 75-59-2 |
| DIW | Deionized Water | 7732-18-5 |
| Fluorosilicic Acid | Fluorosilicic acid | 16961-83-4 |
| (33.5-35%) | | |
| NH₄OH (29%) | NH₄OH | 1336-21-6 |

### General Procedure for Preparing the Etching Compositions

All compositions set forth in the Examples were prepared by mixing the components in a 250 mL beaker with a 1″ Teflon-coated stir bar. Typically, the first material added to the beaker was deionized (DI) water.

### Compositions of the Substrate

Each test coupon employed in the examples included a 20 mm×20 mm polysilicon wafer, alpha silicon wafer and TEOS oxide wafer.

### Processing Conditions

Etching tests were run using 100 g of the etching compositions in a 250 mL beaker with a 1″ Teflon-coated stir bar set at 500 rpm. The etching compositions were heated to a temperature of about 25° C. to about 90° C. on a hot plate. The polysilicon and pattern test substrate pieces (test coupons) were treated with DHF (1:100 HF: DI water) for about 3 minutes prior to testing. the SiOx test coupons were not pretreated with DHF. The test coupons were immersed in the compositions for about 1 (for Silicon substrates) to about 90 (for SiOx substrates) minutes while stirring.

The segments were then rinsed for about 3 minutes in a DI water bath or spray and subsequently dried using filtered nitrogen. The silicon and silicon oxide etch rates were estimated from changes in the thickness before and after etching and was measured by spectroscopic ellipsometry (FilmTek™ 2000 PAR-SE, Scientific Computing International).

The following series of Tables show the evaluation results of several embodiments of the disclosed and claimed etching compositions. All example values are reported as “neat” values unless noted otherwise. Additionally, performance wafer testing was not conducted on samples that did not satisfy the selectivity or etch rate requirements.

TABLE 1
Effect of Different Si-containing Oxide Inhibitors in NH₄OH

| | | Ex. 1 | | |
|---|---|---|---|---|
| Raw Material | RM Assay (wt %) | (1:50 NH₄OH) | Ex. 2 | Ex. 3 |
| NH₄OH | 29 | 0.58 | 0.58 | 0.58 |
| DIW | 100 | 99.42 | 99.095 | 99.4025 |
| Si Compound 1 | 32.5 | — | 0.325 | — |
| Fluorosilicic Acid | 33.5-35 | — | — | 0.0175 |
| Total | | 100.00 | 100.00 | 100.00 |
| Temperature | | 60 | 60 | 60 |
| a-Si E/R (Å/min.) | | 158.7 | 166.6 | 157.9 |
| TEOS E/R (Å/min.) | | 0.571 | 0.113 | 0.131 |
| a-Si/TEOS selectivity | | 277.9 | 1474.3 | 1205.3 |
| Performance on | SiOx Compatibility | Compatible | — | — |
| Patterned Wafer | Clean Performance | Severe Si residue | — | — |
| (Process time = | | remained | | |
| 90 min.) | | | | |

Table 1 demonstrates that the silicon oxide etch rate can be suppressed by adding an Si containing compound of Formula II and fluorosilicic acid in an NH₄OH solution while the silicon etch rate is maintained at the same level.

TABLE 2
Effect of Different Si-containing
Oxide Inhibitors in QAH (ETMAH)

| Raw Material | RM Assay (wt %) | Ex. 4 | Ex. 5 | Ex. 6 |
|---|---|---|---|---|
| ETMAH | 20 | 0.4 | 0.4 | 0.4 |
| Si Compound 1 | 32.5 | — | 0.325 | — |
| Fluorosilicic Acid | 33.5-35 | — | — | 0.0175 |
| DIW | 100 | 99.6 | 99.275 | 99.5825 |
| Total | | 100.00 | 100.00 | 100.00 |
| Temperature | | 60 | 60 | 60 |
| a-Si E/R (Å/min.) | | 329.9 | 309.1 | 307.6 |
| TEOS E/R (Å/min.) | | 0.923 | 0.169 | 0.658 |
| a-Si/TEOS selectivity | | 357.4 | 1829.0 | 467.5 |
| Performance on | SiOx | — | — | — |
| Patterned Wafer | Compatibility | | | |
| (Process time = | Clean | — | — | — |
| 90 min.) | Performance | | | |

Table 2 demonstrates that the silicon oxide etch rate can be suppressed by adding a Si containing compound of Formula II and fluorosilicic acid in a QAH solution. As can be seen, the Si containing compound showed better protection capability. Additionally, the silicon etch rate is much higher by employing QAH as an alkaline source and also kept the same level while adding Si containing compound and fluorosilicic acid.

TABLE 3
Effect of Different Concentrations of ETMAH

| Raw Material | RM Assay (wt %) | Ex. 7 | Ex. 8 | Ex. 9 | Ex. 10 | Ex. 11 | Ex. 12 |
|---|---|---|---|---|---|---|---|
| ETMAH | 20 | 0.25 | 0.3 | 0.35 | 0.4 | 0.5 | 0.6 |
| DIW | 100 | 99.425 | 99.375 | 99.325 | 99.275 | 99.175 | 99.075 |
| Si Compound 1 | 32.5 | 0.325 | 0.325 | 0.325 | 0.325 | 0.325 | 0.325 |
| Total | | 100.00 | 100.00 | 100.00 | 100.00 | 100.00 | 100.00 |
| Temperature | | 60 | 60 | 60 | 60 | 60 | 60 |
| a-Si E/R (Å/min.) | | 175.3 | 240.6 | 286.0 | 309.1 | 414.4 | 440.4 |
| TEOS E/R (Å/min.) | | 0.096 | 0.132 | 0.157 | 0.169 | 0.268 | 0.427 |
| a-Si/TEOS selectivity | | 1826.0 | 1822.7 | 1821.7 | 1829.0 | 1546.3 | 1031.4 |
| Performance on | SiOx | — | Compatible | Compatible | Compatible | — | — |
| Patterned Wafer | Compatibility | | | | | | |
| (Process time = | Clean | — | Some Si | Some Si | Some Si | — | — |
| 90 min.) | Performance | | residue | residue | residue | | |
| | | | remained | remained | remained | | |

Table 3 further shows that the silicon etch rate can be promoted while introducing a higher content of QAH, but that the Si to SiOx selectivity becomes lower.

TABLE 4
Effect of Temperature

| Raw Material | RM Assay (wt %) | Ex. 10 | Ex. 10 | Ex. 10 | Ex. 10 | Ex. 10 |
|---|---|---|---|---|---|---|
| ETMAH | 20 | 0.4 | 0.4 | 0.4 | 0.4 | 0.4 |
| DIW | 100 | 99.275 | 99.275 | 99.275 | 99.275 | 99.275 |
| Si Compound 1 | 32.5 | 0.325 | 0.325 | 0.325 | 0.325 | 0.325 |
| Total | | 100.00 | 100.00 | 100.00 | 100.00 | 100.00 |
| Temperature | | 60 | 65 | 70 | 75 | 80 |
| a-Si E/R (Å/min.) | | 309.1 | 364.4 | 560.2 | 720.4 | 947.6 |
| TEOS E/R (Å/min.) | | 0.169 | 0.283 | 0.500 | 0.682 | 1.252 |
| a-Si/TEOS selectivity | | 1829.0 | 1287.6 | 1120.4 | 1056.3 | 756.9 |
| Performance on | SiOx | Compatible | — | — | Compatible | — |
| Patterned Wafer | Compatibility | | | | | |
| (Process time = | Clean | Some Si | — | — | Slight Si | — |
| 90 min.) | Performance | residue | | | residue | |
| | | remained | | | remained | |

Table 4 shows the effects on the formulation of Ex. 10 when used to etch at varying temperatures. As seen in Table 4, the silicon etch rate can be promoted by raising the process temperature, but the Si to SiOx selectivity becomes lower. Additionally, silicon residue still can not be removed with such high etch rate at 75° C.

TABLE 5
Evaluation of Different Concentrations of Si Compound 1

| Raw Material | RM Assay (wt %) | Ex. 13 | Ex. 10 | Ex. 14 | Ex. 15 |
|---|---|---|---|---|---|
| ETMAH | 20 | 0.4 | 0.4 | 0.4 | 0.4 |
| DIW | 100 | 99.6 | 99.275 | 99.1125 | 98.95 |
| Si Compound 1 | 32.5 | — | 0.325 | 0.4875 | 0.65 |
| Total | | 100.00 | 100.00 | 100.00 | 100.00 |
| Temperature | | 75 | 75 | 75 | 75 |
| a-Si E/R (Å/min.) | | 825.3 | 720.4 | 648.6 | 346.5 |
| TEOS E/R (Å/min.) | | 3.327 | 0.682 | 0.454 | 0.241 |
| a-Si/TEOS selectivity | | 248.1 | 1056.3 | 1428.6 | 1437.8 |
| Performance on | SiOx | — | Compatible | Compatible | — |
| Patterned Wafer | Compatibility | | | | |
| (Process time = | Clean | — | Slight Si | Slight Si | — |
| 90 min.) | Performance | | residue | residue | |
| | | | remained | remained | |

Table 5 shows that the silicon oxide etch rate is high while processing at 75° C. As can be seen the silicon oxide etch rate is suppressed by adding more Si containing compound.

TABLE 6
Different water to solvent (MEA) ratio (QAH = ETMAH)

| Raw Material | RM Assay (wt %) | Ex. 14 | Ex. 16 | Ex. 17 | Ex. 18 | Ex. 19 |
|---|---|---|---|---|---|---|
| ETMAH | 20 | 0.4 | 0.4 | 0.4 | 0.4 | 0.4 |
| DIW | 100 | 99.1125 | 52.6125 | 39.1125 | 29.1125 | 22.6125 |
| Si Compound 1 | 32.5 | 0.4875 | 0.4875 | 0.4875 | 0.4875 | 0.4875 |
| MEA | 100 | — | 46.50 | 60.00 | 70.00 | 76.50 |
| Total | | 100.00 | 100.00 | 100.00 | 100.00 | 100.00 |
| Temperature | | 75 | 75 | 75 | 75 | 75 |
| a-Si E/R (Å/min.) | | 648.6 | 657.3 | 674.3 | 694.3 | 519.6 |
| TEOS E/R (Å/min.) | | 0.454 | 0.291 | 0.232 | 0.012 | 0.002 |
| a-Si/TEOS selectivity | | 1428.6 | 2258.8 | 2906.5 | 57858.3 | 259800.0 |
| Performance on | SiOx | Compatible | Compatible | Compatible | Compatible | Compatible |
| Patterned Wafer | Compatibility | | | | | |
| (Process time = | Clean | Slight Si | Clean | Clean | Something | Something |
| 90 min.) | Performance | residue | | | remained | remained |
| | | remained | | | on surface | on surface |

Table 6 shows the ability of several of the disclosed and claimed formulations to remove silicon residue on a patterned structure by introducing a varying levels of alkanolamine. It should be noted that residual materials also remained on the wafer surface when the solvent to water ratio is too high (e.g., greater than about 2.4; see Ex. 18).

TABLE 7
Evaluation of Different Concentrations of Si Compound 1

| Raw Material | RM Assay (wt %) | Ex. 16 | Ex. 20 | Ex. 21 |
|---|---|---|---|---|
| ETMAH | 20 | 0.4 | 0.4 | 0.4 |
| DIW | 100 | 52.6125 | 52.95 | 53.625 |
| Si Compound 1 | 32.5 | 0.4875 | 0.65 | 0.975 |
| MEA | 100 | 46.50 | 46.00 | 45.00 |
| Total | | 100.00 | 100.00 | 100.00 |
| Temperature | | 75 | 75 | 75 |
| a-Si E/R (Å/min.) | | 657.3 | 672.2 | 656.2 |
| TEOS E/R (Å/min.) | | 0.291 | 0.184 | 0.116 |
| a-Si/TEOS selectivity | | 2258.8 | 3653.3 | 5656.9 |
| Performance on | SiOx | Compatible | — | — |
| Patterned Wafer | Compatibility | | | |
| (Process time = | Clean | Clean | — | — |
| 90 min.) | Performance | | | |

Table 7 shows that the silicon oxide etch rate can also be suppressed by adding more of the Si containing compound while the alkanolamine is introduced.

TABLE 8
Effect of Different Concentrations of ETMAH

| Raw Material | RM Assay (wt %) | Ex. 16 | Ex. 22 | Ex. 23 |
|---|---|---|---|---|
| ETMAH | 20 | 0.4 | 1.00 | 2.00 |
| DIW | 100 | 52.6125 | 52.0125 | 51.0125 |
| Si Compound 1 | 32.5 | 0.4875 | 0.4875 | 0.4875 |
| MEA | 100 | 46.50 | 46.50 | 46.50 |
| Total | | 100.00 | 100.00 | 100.00 |
| Temperature | | 75 | 75 | 75 |
| a-Si E/R (Å/min.) | | 657.3 | — | — |
| Polysilicon E/R (Å/min.) | | 1296.3 | 1445.1 | 1862.1 |
| TEOS film loss (Å), 90 min. | | 0.291 | 0.874 | 1.226 |
| a-Si/TEOS selectivity | | 2258.8 | — | — |
| Polysilicon/TEOS selectivity | | 4454.6 | 1653.4 | 1518.8 |
| Performance on | SiOx | Compatible | — | — |
| patterned Wafer | Compatibility | | | |
| (Process time = | Clean | Clean | — | — |
| 90 min.) | Performance | | | |

Table 8 demonstrates that the polysilicon etch rate can be increased by increasing the QAH content.

TABLE 9
Different Water to Solvent (MEA) Ratios (QAH = TMAH)

| Raw Material | RM Assay (wt %) | Ex. 24 | Ex. 25 | Ex. 26 | Ex. 27 |
|---|---|---|---|---|---|
| TMAH | 25 | 2.00 | 2.00 | 2.00 | 2.00 |
| DIW | 100 | 52.514 | 47.514 | 42.514 | 37.514 |
| Si Compound 1 | 45 | 0.486 | 0.486 | 0.486 | 0.486 |
| MEA | 100 | 45.00 | 50.00 | 55.00 | 60.00 |
| Total | | 100.00 | 100.00 | 100.00 | 100.00 |
| Temperature | | 75 | 75 | 75 | 75 |
| Polysilicon E/R (Å/min.) | | 2081.5 | 2050.4 | 1709.0 | 1590.9 |
| TEOS E/R (Å/min), 90 min. | | 1.289 | 0.960 | 0.670 | 0.587 |
| Polysilicon/TEOS selectivity | | 1614.8 | 2135.8 | 2550.7 | 2710.2 |
| Performance on | SiOx | — | Compatible | — | Compatible |
| Patterned Wafer | Compatibility | | | | |
| (Process time = | Clean | — | Clean | — | Some Si residue |
| 90 min.) | Performance | | | | remained |

Table 9 demonstrates compositions using TMAH as the QAH.

TABLE 10
Effect of 2.38% TMAH (neat)

| Raw Material | RM Assay (wt %) | Ex. 28 |
|---|---|---|
| TMAH | 25 | 2.375 |
| DIW | 100 | 97.625 |
| Total | | 100.00 |
| Temperature | | 65 |
| Polysilicon E/R (Å/min.) | | 1923.50 |
| TEOS E/R (Å/min), 90 min. | | 1.600 |
| Polysilicon/TEOS Selectivity | | 1202.2 |
| Performance on Patterned Wafer | SiOx | Compatible |
| (Process time = 90 min.) | Compatibility | |
| | Clean | Slight Si residue |
| | Performance | remained |

Table 10 provides a comparative formulation using about 2.4 wt % of TMAH. As can be seen, the TMAH formulations of Table 9 exhibit superior Si to SiOx selectivity and residue removal than a TMAH-only composition.

### SUMMARY

The disclosed and claimed subject matter is directed to a semi-aqueous etching composition for polysilicon exhume application. Compared to conventional alkaline solution, the formulated chemistry can completely remove polysilicon without residue by processing with comparable process time and no damage on SiOx was observed. Significantly, the disclosed and claims compositions include Si-containing oxide inhibitors that to suppress oxide etch rate and promote Si to SiOx selectivity in alkaline chemistry. Moreover, the cleaning performance of the disclosed and claimed compositions can be “tuned” to specific application by controlling the water to solvent ratio.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. An etching composition comprising:
A. about 20 wt % to about 65 wt % of water;
B. one or more alkanolamine of Formula I: 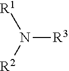
wherein R¹, R² and R³ are each independently selected from:
(a) hydrogen,
(b1) a C₁-C₂₀ straight chain alkyl group,
(b2) a C₄-C₂₀ branch chain alkyl group,
(b3) a C₃-C₂₀ cyclic alkyl group;
(c) an unsubstituted C₂-C₂₀ alkyl ether group;
(d) a C₁-C₂₀ alkanol group
(e) a C₂-C₂₀ alkyl ether group substituted with an —OH group, and wherein at least one of R¹, R² and R³ must be (d) or (e);
C. about 0.1 wt % to about 3 wt % of one or more quaternary ammonium hydroxide; and
D. 0.15 wt % to about 2.0 wt % neat of one or more silicon-containing compound of Formula II: 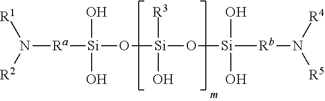
wherein:
(i) m=0-20,
(ii) each of R¹, R², R³, R⁴ and R⁵ is independently selected from the group of hydrogen, a C₁ to C₁₀ linear alkyl group, a C₁ to C₁₀ linear alkyl group substituted with fluorine, a nitrogen-containing group, an oxygen-containing group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group, 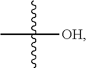 [SMILES: *O]
and
(iii) each of R^{a} and R^{b} is independently selected from a C₁ to C₁₀ linear alkyl group, a C₃ to C₁₀ branched alkyl group, a C₃ to C₁₀ cyclic alkyl group, a C₅ to C₁₂ aryl group, a C₂ to C₁₀ linear or branched alkenyl group and a C₂ to C₁₀ linear or branched alkynyl group 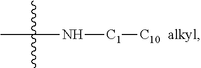
a C₁-C₁₀ alkyl substituted with

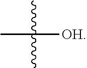 [SMILES: *O]

2-6. (canceled)

7. The etching composition of claim 1, wherein the one or more alkanolamine of Formula I comprises monoethanolamine (MEA).

8-10. (canceled)

11. The etching composition of claim 1, wherein the one or more quaternary ammonium hydroxide comprises one or more of ETMAH and TMAH.

12-27. (canceled)

28. The composition of claim 1, wherein the one or more silicon-containing compound of Formula II comprises

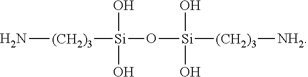

29-33. (canceled)

34. The etching composition of claim 1, comprising:
A. about 35 wt % to about 60 wt % of water;
B. about 20.0 to about 70.0 wt % of monoethanolamine (MEA);
C. about 0.1 wt % to about 3 wt % of neat ethyltrimethylammonium hydroxide (ETMAH) or of neat tetramethylammonium hydroxide (TMAH); and
D. about 0.15 wt % to about 2.0 wt % of neat

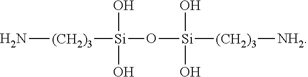

35. The composition of claim 1, wherein the composition further comprises one or more additional silicon-containing compound selected from alkylsilsesquioxanes, vinylsilsesquioxane, carboxylic acid alkylsilsesquioxane and alkyleneglycol alkylsilsesquioxane.

36. The composition of claim 1, wherein the composition further comprises one or more hydroxyl group-containing water-miscible solvent selected from the group of alkane diols, polyols, glycols, alkoxyalcohols, saturated aliphatic monohydric alcohols, unsaturated non-aromatic monohydric alcohols, and low molecular weight alcohols containing a ring structure.

37. The composition of claim 1, wherein the composition further comprises one or more silicic acid.

38. The composition of claim 1, wherein the composition further comprises one or more surfactant.

39. The etching composition of claim 1, comprising:
A. about 20 wt % to about 55 wt % of water;
B. about 20 wt % to about 70 wt % of monoethanolamine (MEA);
C. about 0.1 wt % to about 2.5 wt % of neat ethyltrimethylammonium hydroxide (ETMAH); and
D. about 0.3 wt % to about 1.25 wt % of neat

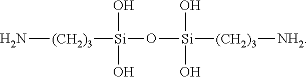

40. The etching composition of claim 1, comprising:
A. about 52.6 wt % of water;
B. about 46.5 wt % of monoethanolamine (MEA);
C. about 0.4 wt % of neat ethyltrimethylammonium hydroxide (ETMAH); and
D. about 0.5 wt % of neat

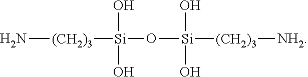

41. The etching composition of claim 1, comprising:
A. about 39 wt % of water;
B. about 60 wt % of monoethanolamine (MEA);
C. about 0.4 wt % of neat ethyltrimethylammonium hydroxide (ETMAH); and
D. about 0.5 wt % of neat

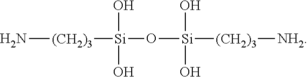

42. (canceled)

43. The etching composition of claim 1, comprising:
A. about 29 wt % of water;
B. about 70 wt % of monoethanolamine (MEA);
C. about 0.4 wt % of neat ethyltrimethylammonium hydroxide (ETMAH); and
D. about 0.5 wt % of neat

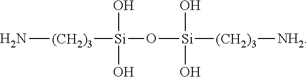

44-46. (canceled)

47. The etching composition of claim 1, comprising:
A. about 53 wt % of water;
B. about 46 wt % of monoethanolamine (MEA);
C. about 0.4 wt % of neat ethyltrimethylammonium hydroxide (ETMAH); and
D. about 0.6 wt % of neat

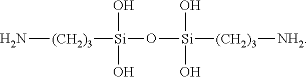

48. (canceled)

49. The etching composition of claim 1, comprising:
A. about 53.6 wt % of water;
B. about 45 wt % of monoethanolamine (MEA);
C. about 0.4 wt % of neat ethyltrimethylammonium hydroxide (ETMAH); and
D. about 1 wt % of neat

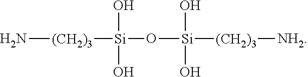

50. (canceled)

51. The etching composition of claim 1, comprising:
A. about 52 wt % of water;
B. about 46.5 wt % of monoethanolamine (MEA);
C. about 1 wt % of neat ethyltrimethylammonium hydroxide (ETMAH); and
D. about 0.5 wt % of neat

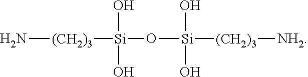

52. (canceled)

53. The etching composition of claim 1, comprising:
A. about 51 wt % of water;
B. about 46.5 wt % of monoethanolamine (MEA);
C. about 2 wt % of neat ethyltrimethylammonium hydroxide (ETMAH); and
D. about 0.5 wt % of neat

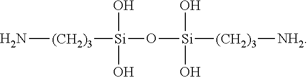

54. (canceled)

55. The etching composition of claim 1, comprising:
A. about 45 wt % to about 55 wt % of water;
B. about 40 wt % to about 55 wt % of monoethanolamine (MEA);
C. about 0.1 wt % to about 2.5 wt % of neat tetramethylammonium hydroxide (TMAH); and
D. about 0.4 wt % to about 0.95 wt % of neat

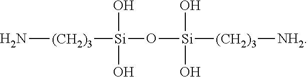

56. The etching composition of claim 1, comprising:
A. about 52.5 wt % of water;
B. about 45 wt % of monoethanolamine (MEA);
C. about 2 wt % of neat tetramethylammonium hydroxide (TMAH); and
D. about 0.5 wt % of neat

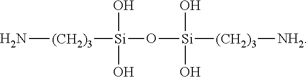

57. The etching composition of claim 1, comprising:
A. about 47.5 wt % of water;
B. about 50 wt % of monoethanolamine (MEA);
C. about 2 wt % of neat tetramethylammonium hydroxide (TMAH); and
D. about 0.5 wt % of neat

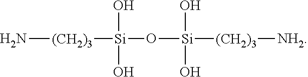

58. The etching composition of claim 1, comprising:
A. about 47.514 wt % of water;
B. about 50 wt % of monoethanolamine (MEA);
C. about 2 wt % of neat tetramethylammonium hydroxide (TMAH); and
D. about 0.5 wt % of neat

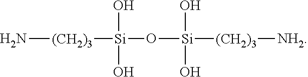

59. The etching composition of claim 1, comprising:
A. about 42.5 wt % of water;
B. about 55 wt % of monoethanolamine (MEA);
C. about 2 wt % of neat tetramethylammonium hydroxide (TMAH); and
D. about 0.5 wt % of neat

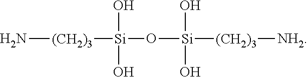

60. The etching composition of claim 1, comprising:
A. about 42.514 wt % of water;
B. about 55 wt % of monoethanolamine (MEA);
C. about 2 wt % of neat tetramethylammonium hydroxide (TMAH); and
D. about 0.486 wt % of neat

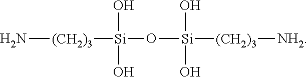

61. The etching composition of claim 1, comprising:
A. about 37.5 wt % of water;
B. about 60 wt % of monoethanolamine (MEA);
C. about 2 wt % of neat tetramethylammonium hydroxide (TMAH); and
D. about 0.5 wt % of neat

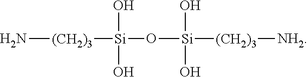

62. The etching composition of claim 1, comprising:
A. about 37.514 wt % of water;
B. about 60 wt % of monoethanolamine (MEA);
C. about 2 wt % of neat tetramethylammonium hydroxide (TMAH); and
D. about 0.486 wt % of neat

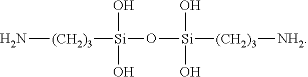

63-71. (canceled)

72. A method of selectively enhancing the etch rate of silicon relative to silicon dioxide on a semiconductor substrate comprising silicon and silicon dioxide, the method comprising the steps of:
a. contacting the semiconductor substrate comprising silicon and silicon dioxide with the composition of claim 1; and
b. rinsing the semiconductor device after the silicon is at least partially removed.

73. (canceled)

74. (canceled)
